(19) United States
(12) Patent Application Publication
(10) Pub. No.: US 2025/0324633 A1
(43) Pub. Date: Oct. 16, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Shih-Hsin Chao, Kaohsiung City (TW); Yen-Hsiu Wu, Kaohsiung City (TW); Ching-Chang Hsu, Tainan City (TW); Cheng-Fang Chen, Tainan City (TW); Wen-Kuei Hsieh, Tainan City (TW); Kao-Tien Lin, Kaohsiung City (TW); Jung-Chang Wang, Kaohsiung City (TW); Hsin-Chieh Chen, Tainan City (TW); Yu-Lung Chang, Kaohsiung City (TW); Ching-Yi Chuang, Taichung City (TW)

(73) Assignee: UNITED MICROELECTRONICS CORP., Hsin-Chu City (TW)

(21) Appl. No.: 18/675,122

(22) Filed: May 27, 2024

(30) Foreign Application Priority Data
Apr. 16, 2024 (TW) 113114113

(51) Int. Cl. H01L 29/66; H01L 29/423; H01L 29/78

(52) U.S. Cl. CPC H10D 30/022; H10D 30/601; H10D 64/021; H10D 64/514

(57) ABSTRACT

A method for fabricating semiconductor device includes the steps of first forming a gate dielectric layer on a substrate, forming a gate electrode on the gate dielectric layer, forming a first spacer adjacent to the gate electrode, forming a lightly doped drain (LDD) in the substrate adjacent to the first spacer, forming a second spacer adjacent to the first spacer, removing part of the gate dielectric layer, and then forming a source/drain region in the substrate.

### BACKGROUND OF THE INVENTION

### 1. Field of the Invention

The invention relates to a method for fabricating semiconductor device, and more particularly to a method of adjusting the timing of patterning a gate dielectric layer for improving gate-induced-drain leakage (GIDL).

### 2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal gate transistor in particularly during the formation of medium-voltage (MV) devices when doped regions such as lightly doped drains (LDDs) or source/drain regions are too close to the gate electrode, problem such as gate-induced-drain-leakage (GIDL) often arise. Hence, how to resolve this issue has become an important task in this field.

### SUMMARY OF THE INVENTION

According to an embodiment of the present invention, a method for fabricating semiconductor device includes the steps of first forming a gate dielectric layer on a substrate, forming a gate electrode on the gate dielectric layer, forming a first spacer adjacent to the gate electrode, forming a lightly doped drain (LDD) in the substrate adjacent to the first spacer, forming a second spacer adjacent to the first spacer, removing part of the gate dielectric layer, and then forming a source/drain region in the substrate.

According to another aspect of the present invention, a semiconductor device includes a gate dielectric layer on a substrate, a gate electrode on the gate dielectric layer, a first spacer adjacent to the gate electrode, a lightly doped drain (LDD) in the substrate adjacent to the first spacer, and a second spacer adjacent to the first spacer and on the gate dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-7, FIGS. 1-7 illustrate a method for fabricating semiconductor device according to an embodiment of the present invention. As shown in FIG. 1, a substrate 12 is first provided, in which the substrate 12 could be a silicon substrate or silicon-on-insulator (SOI) substrate. A transistor region used for preparing a MV device could be defined on the substrate 12, in which the transistor region could include a PMOS region or a NMOS region. It should be noted that even though the present invention pertains to a method for fabricating planar field effect transistor (FET), according to other embodiment of the present invention, the following process could also be employed for fabricating non-planar devices such as fin field effect transistor (FinFET) device. In this instance, the substrate 12 shown in FIG. 1 would then be a fin-shaped structure disposed on the substrate 12.

According to an embodiment of the present invention, the fin-shaped structures could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures could also be obtained by first forming a patterned mask (not shown) on the substrate, 12, and through an etching process, the pattern of the patterned mask is transferred to the substrate 12 to form the fin-shaped structure. Moreover, the formation of the fin-shaped structures could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structures. These approaches for forming fin-shaped structures are all within the scope of the present invention.

Next, at least a gate structure or dummy gate is formed on the substrate 12. In this embodiment, the formation of the gate structure could be accomplished by a gate first process, a high-k first approach from gate last process, or a high-k last approach from gate last process. Since this embodiment pertains to a high-k last approach, a gate dielectric layer 14 or interfacial layer, a gate material layer 16 made of polysilicon, and a selective hard mask 20 could be formed sequentially on the substrate 12.

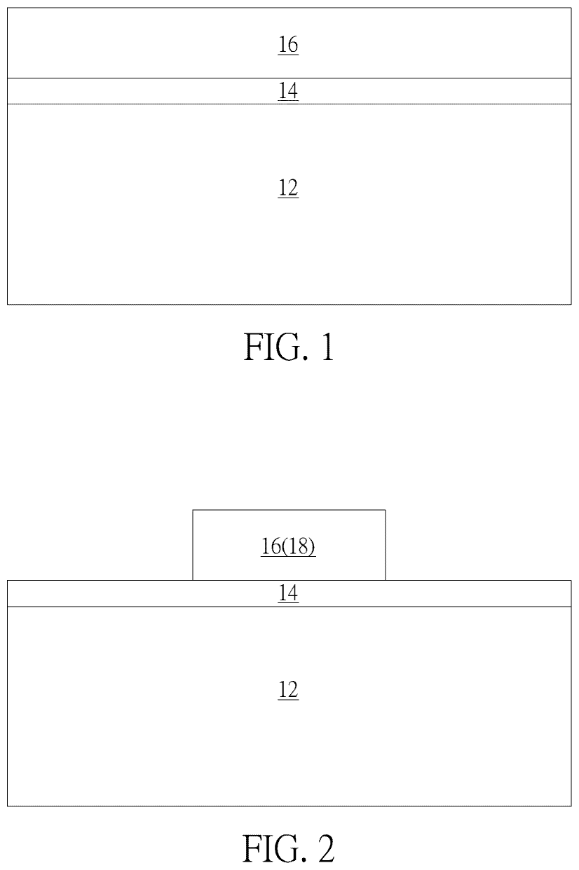

Next, as shown in FIG. 2, a pattern transfer process is conducted by using a patterned resist (not shown) as mask to remove part of the gate material layer 16 through single or multiple etching processes. After stripping the patterned resist, a gate structure or gate electrode 18 made of a patterned gate material layer 16 is formed on the substrate 12. It should be noted that the pattern transfer process conducted at this stage only patterns part of the gate material layer 16 without removing any of the gate dielectric layer 14 under the gate material layer 16. In other words, after patterning the gate material layer 16 to form the gate electrode 18, gate dielectric layer 14 adjacent to two sides of the gate electrode 18 is still disposed to cover the entire substrate 12 surface. Preferably, the gate dielectric layer 14 is made of silicon oxide and since the gate dielectric layer 14 in this embodiment is principally used for MV devices, the thickness of the gate dielectric layer 14 is between 250-350 Angstroms or most preferably 280 Angstroms. The selective hard mask could include silicon nitride of silicon oxide, which are all within the scope of the present invention.

Next, as shown in FIG. 3, a first spacer 20 is formed on sidewalls of the gate electrode 18, and then an ion implantation process is conducted to implant n-type or p-type dopants into the substrate 12 adjacent to two sides of the first spacer 20 for forming a lightly doped drain (LDD) 22. According to an embodiment of the present invention, the formation of the first spacer 20 could be accomplished by first forming a liner (not shown) on the gate dielectric layer 14 and the gate electrode 16 and then conducting an etching back process to remove part of the liner for forming a first spacer 20 on sidewalls of the gate electrode 18. Similarly, the etching back process conducted at this stage preferably not removing any of the gate dielectric layer 14 underneath as part of the liner is removed so that after the first spacer 20 is formed, the gate dielectric layer 14 is still disposed on the entire substrate 12 surface adjacent to two sides of the first spacer 20.

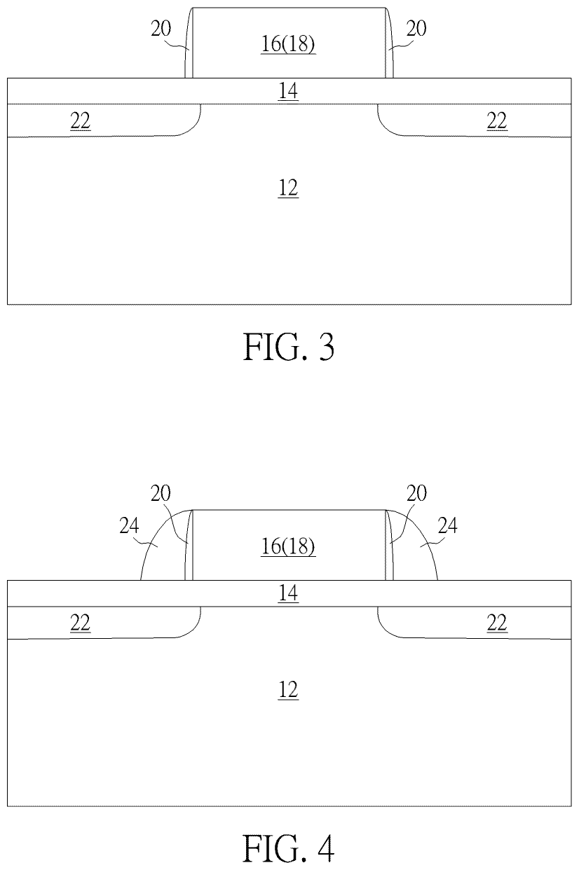

Next, as shown in FIG. 4, after forming the LDD 22, a second spacer 24 is formed adjacent to the first spacer 20. Similar to the formation of the first spacer 20, the formation of the second spacer 24 could be accomplished by first forming a liner (not shown) on the gate dielectric layer 14, the first spacer 20, and the gate electrode 18 and then conducting an etching back process to remove part of the liner for forming a second spacer 24 on sidewalls of the first spacer 20. Similarly, the etching back process conducted at this stage preferably not removing any of the gate dielectric layer 14 underneath as part of the liner is removed so that after the second spacer 24 is formed, the gate dielectric layer 14 is still disposed on the entire substrate 12 surface adjacent to two sides of the second spacer 24.

In this embodiment, each of the first spacer 20 and the second spacer 24 could be a single spacer or composite spacer. For instance, each of the first spacer 20 and the second spacer 24 could further include a single spacer or a composite spacer made of an offset spacer and a main spacer. If each of the first spacer 20 and/or the second spacer 24 were to be a single spacer, the first spacer 20 and the second spacer 24 could include same material or different materials as the spacers 20, 24 could all be selected from the group consisting of SiO₂, SiN, SiON, and SiCN.

If each of the first spacer 20 and the second spacer 24 were to be a composite spacer made of offset spacer and main spacer, the offset and the main spacer could be made of same or different materials. For instance, the offset spacer and the main spacer from the first spacer 20 and the second spacer 24 could all be selected from the group consisting of SiO₂, SiN, SiON, and SiCN, which are all within the scope of the present invention.

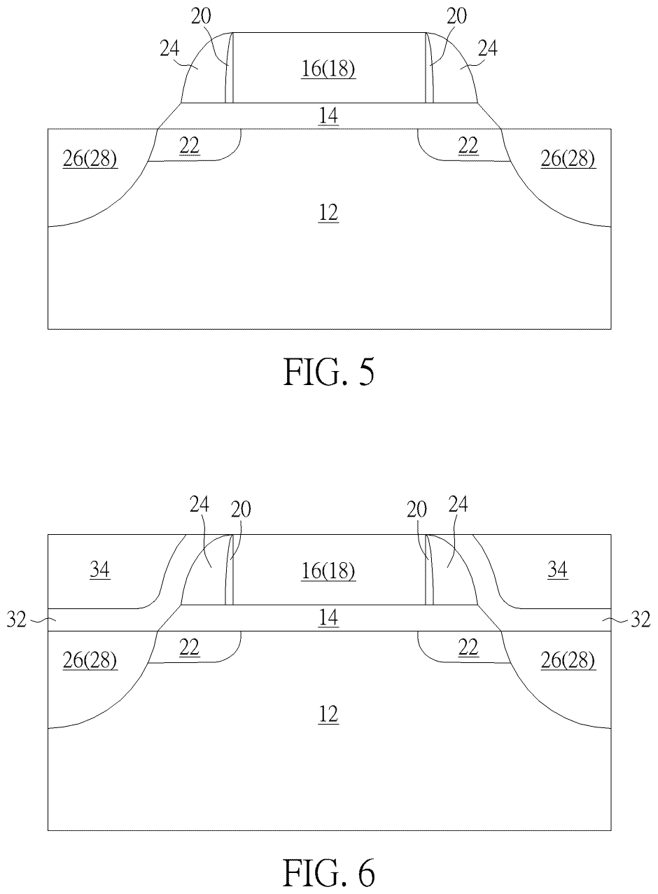

Next, as shown in FIG. 5, an etching process could be conducted by using the second spacer 24 as mask to remove part of the gate dielectric layer 14 adjacent to the second spacer 24, an ion implantation process could be conducted to implant n-type or p-type dopants into the substrate 12 adjacent to two sides of the second spacer 24 for forming a source/drain region or source/drain regions 26, and then a selective epitaxial layer or epitaxial layers 28 could be formed adjacent to two sides of the second spacer 24. It should be noted that after part of the gate dielectric layer 14 is removed by etching process, the remaining sidewalls of the gate dielectric layer 14 preferably form inclined sidewalls as the inclined sidewalls are aligned obliquely with sidewalls of the second spacer 24 to form continuous and non-broken sidewalls altogether. Preferably, an angle included by the inclined sidewalls of the gate dielectric layer 14 and surface of the substrate 12 is between 30-60 degrees or most preferably 45 degrees.

According to an embodiment of the present invention, the epitaxial layers 28 could also be formed to include different materials depending on the type of transistor being fabricated. For instance, if the MOS transistor being fabricated were to be a PMOS transistor, the epitaxial layers 28 could be made of material including but not limited to for example SiGe, SiGeB, or SiGeSn. If the MOS transistor being fabricated were to be a NMOS transistor, the epitaxial layers 28 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 28 are preferred to have less or no germanium atom at all to facilitate the formation of silicide afterwards.

According to an embodiment of the present invention, it would also be desirable to form source/drain regions 26 in part or all of the epitaxial layers 28. According to another embodiment of the present invention, the source/drain regions 26 could also be formed insituly during the SEG process. For instance, the source/drain regions 26 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain regions 26. Moreover, the dopants within the source/drain regions 26 could also be formed with a gradient, which is also within the scope of the present invention.

Next, as shown in FIG. 6, a selective contact etch stop layer (CESL) 32 could be formed on the surface of the gate electrode 18 and the second spacer 24 and an interlayer dielectric (ILD) layer 34 is formed on the CESL 32. Next, a planarizing process such as chemical mechanical polishing (CMP) process is conducted to remove part of the ILD layer 34 and part of the CESL 32 for exposing the gate material layer 16 made of polysilicon so that the top surface of the gate material layer 16 is even with the top surface of the ILD layer 34.

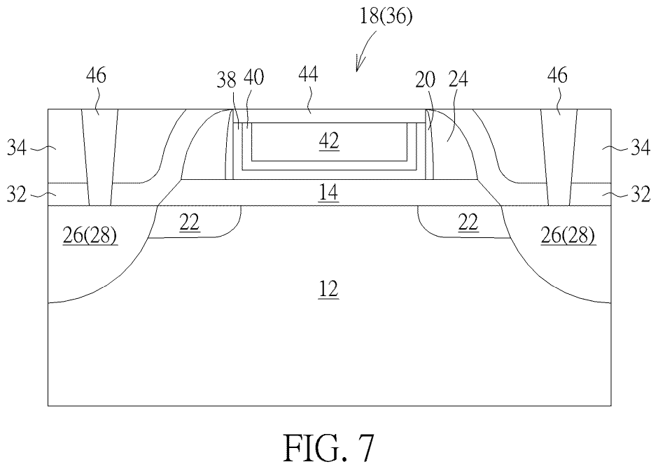

Next, as shown in FIG. 7, a replacement metal gate (RMG) process is conducted to transform the gate electrode 18 into metal gate 36. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 16 for forming a recess (not shown) in the ILD layer 34.

Next, a selective interfacial layer (not shown), a high-k dielectric layer 38, a work function metal layer 40, and a low resistance metal layer 42 are formed in the recess, and a planarizing process such as CMP is conducted to remove part of low resistance metal layer 42, part of work function metal layer 40, and part of high-k dielectric layer 38 to form a metal gate 36. In this embodiment, the gate structure or gate electrode 18 from the metal gate 36 fabricated through high-k last process of a gate last process preferably includes an U-shaped high-k dielectric layer 38, a U-shaped work function metal layer 40, and a low resistance metal layer 42.

In this embodiment, the high-k dielectric layer 38 is preferably selected from dielectric materials having dielectric constant (k value) larger than 4. For instance, the high-k dielectric layer 60 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 40 is formed for tuning the work function of the metal gate in accordance with the conductivity of the device. For an NMOS transistor, the work function metal layer 40 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 40 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 40 and the low resistance metal layer 42, in which the material of the barrier layer may include titanium (Ti), titanium nitride (TiN), tantalum (Ta) or tantalum nitride (TaN). Furthermore, the material of the low-resistance metal layer 42 may include copper (Cu), aluminum (Al), titanium aluminum (TiAl), cobalt tungsten phosphide (CoWP) or any combination thereof.

Next, part of the low resistance metal layer 42, part of the work function metal layer 40, and part of the high-k dielectric layer 38 could be removed to form a recess (not shown), a hard mask 44 is formed into the recess, and a planarizing process is conducted so that the top surface of the hard mask 44 is even with the top surface of the ILD layer 34. In this embodiment, the hard mask 44 could be selected from the group consisting of consisting of SiO₂, SiN, SiON, and SiCN.

Next, a photo-etching process is conducted by using a patterned mask (not shown) as mask to remove part of the ILD layer 34 and part of the CESL 32 adjacent to the gate electrode 18 for forming contact holes (not shown) exposing the source/drain region 26. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 46 electrically connecting the source/drain region 26. This completes the fabrication of a semiconductor device according to an embodiment of the present invention.

Referring again to FIG. 7, FIG. 7 further illustrates a structural view of a semiconductor device according to an embodiment of the present invention. As shown in FIG. 7, the semiconductor device includes a gate dielectric layer 14 disposed on the substrate 12, a gate electrode 18 disposed on the gate dielectric layer 14, a first spacer 20 disposed adjacent to the gate electrode 18, a LDD 22 disposed in the substrate 12 adjacent to the first spacer 20, and a second spacer 24 disposed adjacent to the first spacer 20 and on the gate dielectric layer 14.

Specifically, the first spacer 20 and the second spacer 24 are disposed on the gate dielectric layer 14 at the same time, the thickness of the gate dielectric layer 14 under the second spacer 24 is equal to the thickness of the gate dielectric layer 14 directly under the gate electrode 18, and sidewalls of the gate dielectric layer 14 include inclined sidewalls while an angle included between the inclined sidewall and the substrate 12 surface is between 30-60 degrees or most preferably 45 degrees. Since the width or length of the LDD 22 close to the surface of the substrate 12 is determined by the inclined sidewalls on edge of the gate dielectric layer 14, the width of the LDD 22 closer to the substrate 12 surface in this embodiment is preferably greater than the width of the bottom surface of the second spacer 24.

Typically, part of the gate dielectric layer is removed along sidewalls of the first spacer after forming the first spacer in current fabrication of MV devices and then a second spacer is formed on sidewalls of the first spacer and gate dielectric layer. To prevent doped regions adjacent to two sides of the gate electrode from being too close to the gate electrode, the present invention first forms the first spacer 20, the LDD 22, and the second spacer 24 and then using the second spacer 24 as mask to remove part of the gate dielectric layer along sidewalls of the second spacer while turning sidewalls of the remaining gate dielectric layer into inclined sidewalls. By removing part of the gate dielectric layer after formation of the second spacer, it would be desirable to not only increase effective width of the second spacer, but also reduce problem such as gate-induced-drain-leakage (GIDL) results from doped regions such as LDDs or source/drain regions being too close to the gate electrode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
forming a gate dielectric layer on a substrate;
forming a gate electrode on the gate dielectric layer;
forming a first spacer adjacent to the gate electrode;
forming a lightly doped drain (LDD) in the substrate adjacent to the first spacer;
forming a second spacer adjacent to the first spacer; and
removing part of the gate dielectric layer.

2. The method of claim 1, further comprising:
forming a gate material layer on the gate dielectric layer; and
patterning the gate material layer to form the gate electrode.

3. The method of claim 1, further comprising forming a source/drain region in the substrate after removing part of the gate dielectric layer.

4. The method of claim 1, wherein a sidewall of the gate dielectric layer comprises an inclined sidewall.

5. The method of claim 1, wherein a thickness of the gate dielectric layer under the second spacer is equal to a thickness of the gate dielectric layer under the gate electrode.

6. The method of claim 1, wherein a width of the LDD is greater than a bottom surface of second spacer.

7. A semiconductor device, comprising:
a gate dielectric layer on a substrate;
a gate electrode on the gate dielectric layer;
a first spacer adjacent to the gate electrode;
a lightly doped drain (LDD) in the substrate adjacent to the first spacer; and
a second spacer adjacent to the first spacer and on the gate dielectric layer.

8. The semiconductor device of claim 7, further comprising a source/drain region in the substrate adjacent to two sides of the second spacer.

9. The semiconductor device of claim 7, wherein a sidewall of the gate dielectric layer comprises an inclined sidewall.

10. The semiconductor device of claim 7, wherein a thickness of the gate dielectric layer under the second spacer is equal to a thickness of the gate dielectric layer under the gate electrode.

11. The semiconductor device of claim 7, wherein a width of the LDD is greater than a bottom surface of second spacer.
